(19) United States
(12) Patent Application Publication
(10) Pub. No.: US 2003/0002256 A1
(43) Pub. Date: Jan. 2, 2003

(54) Cooling device for cooling ICs

(76) Inventor: Ichiro Tano, Tokyo (JP)

Correspondence Address: FLYNN, THIEL, BOUTELL & TANIS, P.C., 2026 Rambling Road, Kalamazoo, MI, 49008-1699, US

(21) Appl. No.: 10/180,378

(22) Filed: Jun. 26, 2002

(30) Foreign Application Priority Data
Jun. 27, 2001 (JP) 2001-195284

(51) Int. Cl. H05K 7/20

(52) U.S. Cl. 361/694; 165/126; 174/16.3

(57) ABSTRACT

There is provided a cooling device for ICs capable of relatively uniformly cooling multiple ICs which are arranged in the direction of the supply of wind thereto. Multiple ICs are arranged in the direction of the supply of wind produced in a fan on a printed board. Heat sinks each having fins are disposed on the ICs. A cover is mounted onto each heat sink. The cover has an introduction part which is opened in the direction of the supply of wind, and collects the wind so as to introduce the wind into the heat sink. The wind is changed in its direction as a wind by inclined part of the cover, and the wind is introduced into the introduction part of the cover positioned at downstream side, namely, from the position b to the position h. As a result, each heat sink can be cooled relatively uniformly.

### FIELD OF THE INVENTION

The invention relates to a cooling device for cooling multiple ICs using blower means, more particularly, relates to a cooling device for cooling multiple ICs which are arranged vertically and horizontally in the case of necessity for uniformly cooling the internal temperatures of the multiple ICs. For example, a plurality of printed boards provided with ICs arranged vertically and horizontally are disposed in a test head of an IC tester.

### BACKGROUND OF THE INVENTION

A conventional cooling device 20 for cooling ICs is described with reference to FIG. 4(A) and FIG. 4(B). FIG. 4(A) is a plan view and FIG. 4(B) is a side view of FIG. 4(A). As shown in FIG. 4(A) and FIG. 4(B), the cooling device 20 comprises a fan 3 provided at the end thereof (left side in FIG. 4(A) and FIG. 4(B)) and a printed board 2 provided downstream relative to the fan 3. Multiple ICs 5 are arranged on the printed board 2 in the direction of the supply of wind 4 produced by the fan 3, namely, in the direction from the upstream side to the downstream side, for example, at eight positions a to h. Further, as shown in FIG. 4(B), heat sinks 1 each having multiple pieces of fins 1a are fixed to the upper faces of the ICs 5 by a thermal conductive adhesive and the like.

When the ICs 5 are energized, they are heated. During energization of the ICs 5, the fan is driven so as to supply wind from the position a to the position b as shown by arrows in FIG. 4(A) and FIG. 4(B) (from left to right in these figures). The wind is supplied to multiple cooling plates of each heat sink 1 so that each heat sink 1 radiates heat and is cooled by the wind 4. That is, the wind 4 cools the ICs 5.

However, in the conventional cooling device 20 for cooling the ICs, the wind 4 supplied from the fan is partially blocked out by the heat sink 1 located at the upstream side (position a) to form a wind 4a in FIG. 4(B) and the wind 4a passes over the periphery of each heat sink 1 located at the downstream side (positions b to h). That is, it is difficult to supply the wind 4 uniformly to each heat sink 1, causing a problem that the heat radiation resistance of the IC 5 is apt to sequentially increase at the downstream side (from the position b to the position h) compared with that of the ICs 5 at the position a.

### SUMMARY OF THE INVENTION

The invention has been developed in view of the foregoing circumstances, and it is an object of the invention to provide a cooling device for ICs capable of relatively uniformly cooling multiple ICs which are arranged along the direction of the supply of wind from a fan.

The cooling device 10 for cooling multiple ICs according to the first aspect of the invention has blowing means 3 and arranged in a direction of supply of wind 4 produced in the blowing means, characterized in that the cooling device comprising heat sinks 1 respectively disposed on the multiple ICs 5, covers 6 freely mountable onto the heat sinks 1, said cover 6 having introduction parts 6c which are opened to direct the blowing means when mounted onto the heat sinks, said introduction parts 6c introduces the wind 4 produced by the blowing means into the hest sinks 1.

The cooling device 10 for ICs of the second aspect of the invention is characterized in that each cover 6 has an inclined part 6b for directing the wind 4 toward the introduction part 6c at the downstream side.

The cooling device 10 for ICs of the third aspect of the invention is characterized in that each cover 6 is formed of a plate member capable of clamping the heat sinks 1 owing to elasticity thereof.

The cooling device 10 for ICs of the fourth aspect of the invention is characterized in that each cover 6 is formed in a U-shape in cross section.

Numerals of the constituents as set forth in the first to fourth aspects of the invention are denoted for comparing the constituents with the drawings in view of the convenience to easily understand the invention but not for affecting the scope of the invention, i.e. attached claims.

### BRIEF DESCRIPTION OF THE DRAWINGS

FIG. 1 is a side view of a cooling device 10 for ICs according to a preferred embodiment of the invention.

FIG. 2(A), FIG. 2(B) and FIG. 2(C) are views showing a cover 6 constituting the main portion of the invention, wherein FIG. 2(A) is an exploded view of the cover, FIG. 2(B) is a side view showing a state where the cover 6 is mounted on each heat sink 1, and FIG. 2(C) is a view as viewed from the arrow A in FIG. 2(B).

FIG. 3 is a view for explaining the relation between the position of the ICs and internal temperatures of the ICs in the cooling device for ICs of the present invention and those of the conventional cooling device for ICs.

FIG. 4(A) and FIG. 4(B) are views showing a conventional cooling device for ICs, wherein FIG. 4(A) is a plan view and FIG. 4(B) is a side view.

### PREFERRED EMBODIMENT OF THE INVENTION

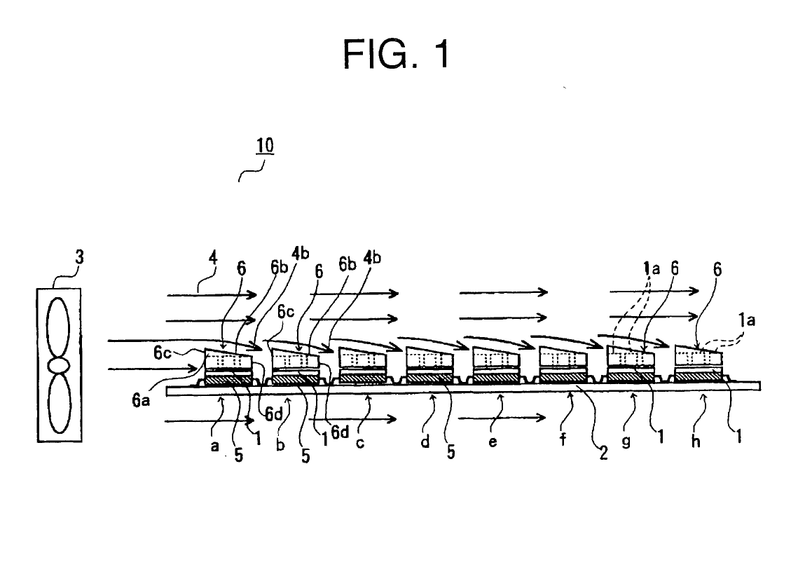

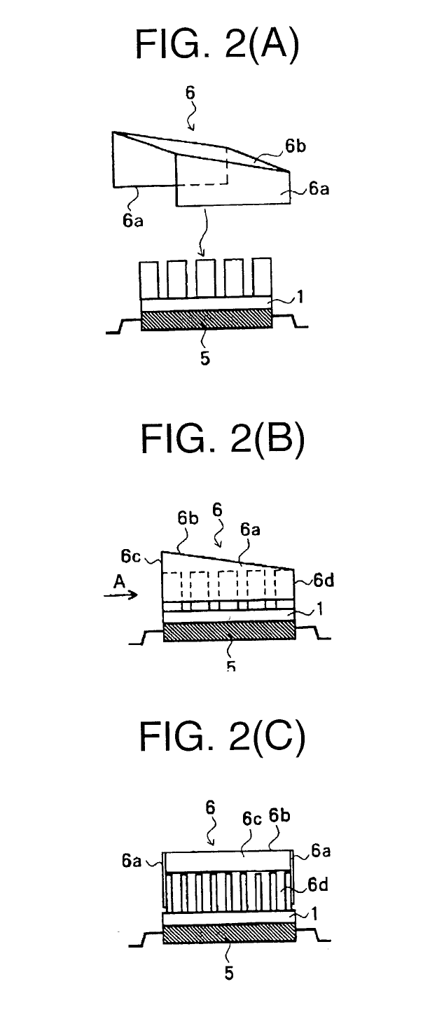

A cooling device for ICs according to a preferred embodiment of the invention is described hereinafter with reference to the attached drawings. FIG. 1 is a side view of a cooling device 10 for ICs according to the preferred embodiment of the invention, FIG. 2(A), FIG. 2(B) and FIG. 2(C) are views showing a cover 6 constituting the main portion of the invention wherein FIG. 2(A) is an exploded view of the cover, FIG. 2(B) is a side view showing a state where the cover 6 is mounted on each heat sink 1, and FIG. 2(C) is a view as viewed from the arrow A in FIG. 2(B).

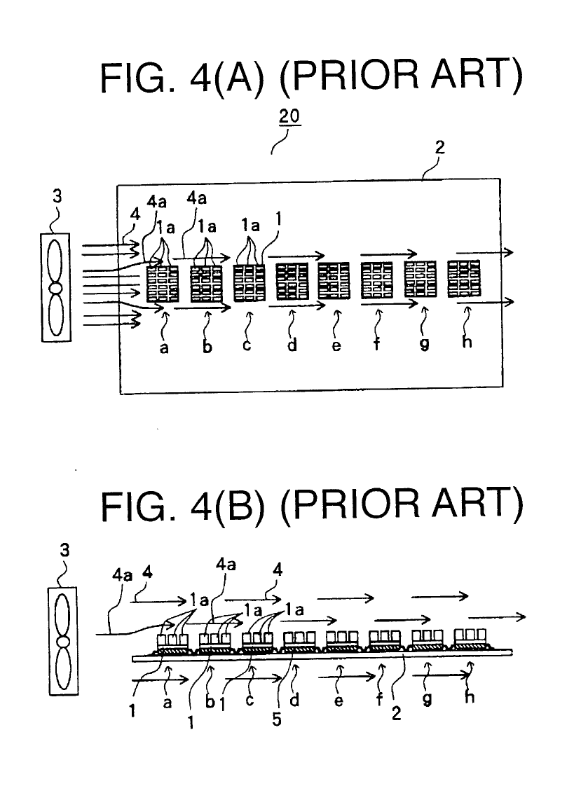

As shown in FIG. 1, the cooling device 10 for ICs of the invention has a fan (cooling means) at the end thereof (left side in FIG. 1) and a printed board 2 disposed at the downstream side of the fan 3 in the same manner as the convention the cooling device 20 for ICs. Multiple ICs 5 are arranged on the printed board 2 in the direction the supply of wind 4 produced by the fan 3, namely, from the upstream side to the downstream side, for example, at eight positions from a, b, c, d, e, f, g and h. Further, heat sinks each having multiple pieces of fins 1a are substantially rectangular as viewed from the above (see FIG. 4(A)) and is substantially parallelepiped rectangular, and they are fixed to the upper face of the ICs 5 by a thermal conductive adhesive and the like. The cover constituting the feature of the invention is mounted on each heat sink 1.

The cover 6 comprises, as shown in FIG. 2(A), an inclined plate (inclined part) 6b provided at an upper part and having a given angle and side parts 6a, 6a provided vertically at both sides of the inclined part 6b, and it has a substantially U-shape in cross section. The side parts 6a, 6a are formed such that the width of each of the lower extremity thereof is slightly smaller than the width of each heat sink 1. When the cover 6 is mounted onto each heat sink 1, the heat sink 1 can be freely clamped by the elasticity of the side parts 6a, 6a. That is, the cover 6 can be freely mountable onto each heat sink 1.

As shown in FIG. 2(B) and FIG. 2(C), when the cover 6 is mounted onto each heat sink 1, there are formed an introduction part 6c which is opened toward the fan 3 for introducing the wind 4 supplied from the fan 3 therein and a vent part 6d which is opened smaller than the inlet part 6c and provided opposite to the introduction part 6c for ventilating the introduced wind 4 (see FIG. 1). The inclined part 6b is inclined in the direction of the supply of wind 4 (from left to the right in FIG. 2(B)).

Described next is a method to cool the ICs 5 by the cooling device 10 for ICs of the invention. First, as shown in FIG. 1, the cover 6 are mounted onto the ICs 5 which are arranged and installed in the direction from the position a to the position h. The wind 4 is produced by the fan 3 and is introduced into the introduction part 6c formed in the cover 6. That is, since the introduction part 6c are relatively large opened in the direction of the supply of wind 4, the wind 4 which normally passes over the heat sinks 1 can be collected by the introduction part 6c so as to be introduced into each heat sink 1 so that each heat sink 1 and each IC 5 can be effectively cooled compared with the conventional case. As a result, the heat radiation resistance of each heat sink 1 can be reduced.

At this time, for example, if the wind 4 supplied over the cover 6 is turned around by the inclined part 6b of the cover 6, e.g. at the position a to form a wind 4b, and the wind 4b is introduced into the introduction part 6c formed in the cover 6 at the position b. Likewise, the wind 4b is introduced into the introduction part 6c by the inclined part 6b at the position b. Subsequently, likewise, the wind 4b is introduced into the introduction part 6c formed in the cover 6 at the downstream side by the inclined part 6b of the cover 6 at the upstream side.

As a result, the wind does not pass over each heat sink 1 as made conventionally like the wind 4a but it can be introduced into the heat sink 1 like the wind 4b. Accordingly, the heat radiation resistance of each heat sink 1 disposed and installed at the downstream side can be lowered, namely, the internal temperatures of the ICs 5 which are arranged and installed at the downstream side, for example, at the position b to the position h can be lowered, so that the multiple ICs 5 which are arranged and installed in the direction of the supply of wind can be uniformly cooled compared with the conventional cooling device for ICs.

For example, when an IC is replaced with another IC, each cover 6 is detached from each heat sink 1, and each IC 5 is detached from the printed board 2. At this time, since each cover 6 is merely mounted onto each heat sink 1 owing to the elasticity of the side plates 6a, 6a, it can be easily detached from each heat sink 1 when the IC is replaced with another IC.

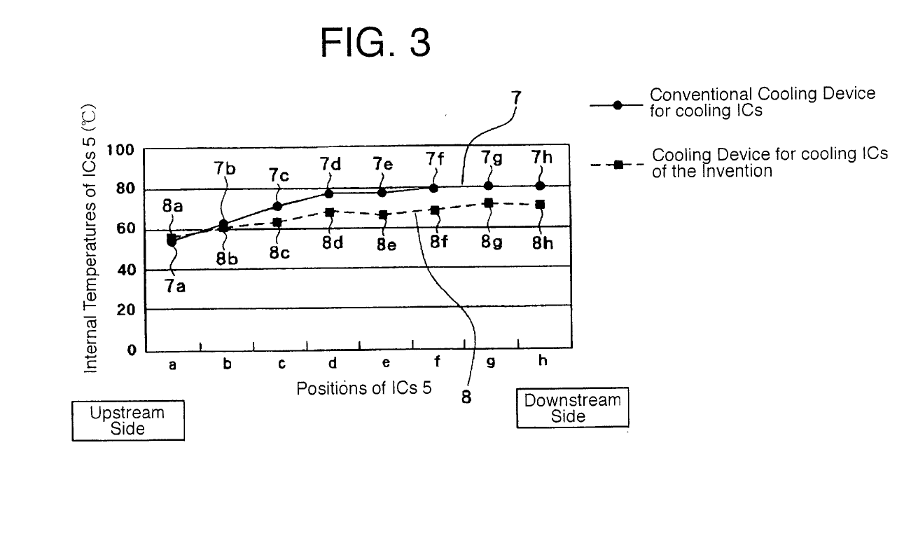

Described next with reference to FIG. 3 is an example of an experiment of the cooling device 10 for ICs according to the invention. FIG. 3 is a view for explaining the relation between the positions of the ICs and the internal temperatures of the ICs in the cooling device for ICs of the present invention and those of the conventional cooling device for ICs. A solid line 7 in FIG. 3 shows the result of experiment using the conventional cooling device 20 for ICs wherein depicted by the numeral 7a to the numeral 7h show internal temperatures of the ICs 5 when using the conventional cooling device 20. Likewise, a broken line 8 in FIG. 3 shows the result of experiment using the cooling device 10 for ICs wherein depicted by the numeral 8a to the numeral 8h show internal temperatures of the ICs 5 when using the cooling device 10 for ICs of the invention.

As shown in FIG. 3, regarding the internal temperature of the IC 5 as installed in the position a, since the wind 4 produced in the fan 3 is supplied to the heat sink 1 without being blocked out, the internal temperature 7a of the IC 5 and the internal temperature 8a of the IC 5 of the invention are the same. However, in the case of using the conventional cooling device 20, the wind 4 is blocked out by the IC 5 and the heat sink 1 installed at the position a so that the internal temperatures 7b to 7h of the ICs 5 at the positions b to h increase sequentially.

On the other hand, when the cooling device 10 for ICs of the invention is used, the wind is introduced from the introduction part 6c of each cover 6 and further the wind 4a which passes over the cover 6 is changed by the inclined part 6b to form the wind 4b which is then introduced into the introduction part 6c located at the downstream so that the internal temperatures 8b to 8h are lowered as a whole compared with the internal temperatures 7b to 7h of the conventional cooling device for ICs. That is, a temperature difference between the maximum temperature and the minimum temperature of the internal temperatures 8a to 8h of the ICs 5 of the invention is lower than that of the internal temperatures 7a to 7h of the conventional ICs 5, that is, the ICs 5 are relatively uniformly cooled. Further, since the maximum temperature is lowered when using the cooling device 10 for ICs of the invention compared with the case of using the conventional cooling device 20, the heat radiation resistance of each heat sink 1 can be reduced as a whole.

With the preferred embodiment of the invention, although each heat sink 1 has multiple heat radiation plates and is substantially rectangular parallelepiped, it may have a disc shaped radiation plate and is substantially cylindrical, or it is not limited to such shapes but may be any shape if it increases a surface area. It is a matter of course that the cover 6 can be freely mounted onto each heat sink 1 while the shape of the cover 6 conforms to that of each heat sink 1.

Although the cooling device 10 for ICs according to the preferred embodiment of the invention is described, for example, when it is used in an IC test system, the cooling device 10 for ICs of the invention can be applied to a case where multiple ICs are arranged and installed in a large scale computer or a personal computer, and it is not limited to such applications, but can be applied to any case where multiple ICs are arranged and installed.

According to the first aspect of the invention, since the cover has introduction parts which are opened to direct the blowing means when mounted onto the heat sinks, and the introduction parts introduces the wind produced by the blowing means into the hest sinks, the wind which normally passes over the heat sink can be collected so as to be introduced into the heat sink so that the heat sink and the IC can be effectively cooled compared with the conventional cooling device for ICs. As a result, the heat radiation resistance can be reduced to lower the internal temperatures of the ICs, thereby improving the reliability, namely, lifespan of the ICs.

According to the second aspect of the invention, since the cover has the inclined part which is inclined conforming to the direction of the supply of wind and the inclined part introduces the wind which is supplied to the introduction part at the downstream side into each heat sink, the heat radiation resistance of the heat sink at the downstream side can be reduced, thereby lowering the internal temperature of the ICs which are arranged and installed at the downstream side, so that the multiple ICs which are arranged and installed in the direction of the supply of wind can be relatively uniformly cooled compared with the conventional cooling device for cooling multiple ICs.

According to the third aspect of the invention, since the cover is formed of a plate member capable of clamping the heat sinks 1 owing to elasticity thereof and is freely mountable onto the heat sink, it can be easily detached from the heat sink when an IC is replaced with another IC.

What is claimed is:

1. A cooling device for cooling multiple ICs having blowing means and arranged in a direction of supply of wind produced in the blowing means, said cooling device comprising:
heat sinks respectively disposed on the multiple ICs;
covers freely mountable onto the heat sinks;
said cover having introduction parts which are opened to direct the blowing means when mounted onto the heat sinks, said introduction parts introduces the wind produced by the blowing means into the hest sinks.

2. The cooling device for ICs according to claim 1, wherein each cover has an inclined part for directing the wind toward the introduction part at the downstream side.

3. The cooling device for ICs according to claim 1 or 2, wherein each cover is formed of a plate member capable of freely clamping the heat sinks owing to elasticity thereof.

4. The cooling device for ICs according to claim 1, wherein each cover is formed in a U-shape in cross section.
